(19) United States
(12) Patent Application Publication
(10) Pub. No.: US 2018/0083047 A1
(43) Pub. Date: Mar. 22, 2018

(54) TFT SUBSTRATE AND MANUFACTURE METHOD THEREOF

(71) Applicant: Wuhan China Star Optoelectronics Technology Co., Ltd., Wuhan City (CN)

(72) Inventor: Tao Wang, Wuhan City (CN)

(21) Appl. No.: 15/039,853

(22) PCT Filed: May 13, 2016
(86) PCT No.: PCT/CN2016/081967

§ 371 Date: May 27, 2016

(30) Foreign Application Priority Data
Apr. 13, 2016 (CN) 201610228341.3

(51) Int. Cl. H01L 27/12; H01L 29/786; H01L 21/027; H01L 21/3065; H01L 29/66; H01L 21/308; G02F 1/1362; G02F 1/1368

(52) U.S. Cl. CPC H01L 27/1222; G02F 2202/104; H01L 29/78675; H01L 29/78618; H01L 29/78633; H01L 27/1248; H01L 27/1288; H01L 21/0273; H01L 21/3065; H01L 29/66757; H01L 21/3081; G02F 1/136227; G02F 1/1368; H01L 27/127; G02F 2001/13685; H01L 27/1218

(57) ABSTRACT

The present invention provides a TFT substrate and a manufacture method thereof. The TFT substrate involves modifications made on the structure of an active layer (410) of a TFT (400) to form at least one step on each of two side portions of the active layer (410). Compared to an active layer of the prior art, electric field concentration effect at acute points on two side surfaces of the active layer (410) can be effectively reduced, making charge carrier concentration in the interior of the active layer (410) uniform and electrical property of output of the TFT (400) stable, whereby the quality of the TFT (400) is made high and the operation stability of the TFT substrate is enhanced. The manufacture method of a TFT substrate according to the present invention effectively reduces electric field concentration effect at acute points on side surfaces of an active layer (410) of a TFT (400), making charge carrier concentration in the interior of the active layer (410) uniform and electrical property of output of the TFT (400) stable, whereby the quality of the TFT (400) is made high and the operation stability of the TFT substrate is enhanced.

### BACKGROUND OF THE INVENTION

### 1. Field of the Invention

The present invention relates to the field of liquid crystal display technology, and in particular to a TFT (Thin-Film Transistor) substrate and a manufacture method thereof.

### 2. The Related Arts

Liquid crystal displays (LCDs) are one of the most widely used flat panel displays and a liquid crystal panel is a core component of the liquid crystal displays.

A conventional liquid crystal display panel is made up of a color filter (CF) substrate, a thin-film transistor (TFT) array substrate, and a liquid crystal layer arranged between the two substrate and the operation principle is that liquid crystal molecules are positioned between two parallel glass substrates with multiple vertical and horizontal tiny conductor wires arranged between the two glass substrates and application of electricity controls the liquid crystal molecules to change direction in order to refract out light emitting from a backlight module to generate an image. The TFT array substrate comprises a TFT array formed thereon for driving the liquid crystal to rotate and controlling a displaying operation of each pixel, while the CF substrate comprises a CF layer formed thereon for generating colors for each pixel.

Referring to FIG. 1, a schematic view is given to show the structure of a conventional TFT substrate, which comprises a backing plate 100′ and a light-shielding layer 200′, a buffer layer 300′, a TFT 400′, a planarization layer 500′, a bottom electrode 600′, a passivation layer 700′, and a top electrode 800′ that are stacked, in a sequence from top to bottom, on the backing plate 100′. The TFT 400′ comprises, arranged in sequence from bottom to top, an active layer 410′, a gate insulation layer 420′, a gate electrode 430′, an interlayer dielectric layer 440′, a source electrode 450′, and a drain electrode 460′. The source electrode 450′ and the drain electrode 460′ extend, respectively, through a first via 910′ and a second via 920′ formed in the gate insulation layer 420′ and the interlayer dielectric layer 440 to respectively connect to two ends of the active layer 410′.

Referring to FIG. 2, which is a top plan view of the TFT included in the TFT substrate of FIG. 1, the TFT 400′ has a top gate structure, and the active layer 410′ is arranged under the gate electrode 430′. The manufacture of the active layer 410′ is conducted by coating mask photoresist on the active layer 410′, followed by dry etching. Referring to FIG. 3, which is a cross-sectional view of the TFT of the TFT substrate of FIG. 1, taken along line A′-A′ of FIG. 2, it can be seen from FIG. 3 that in the lengthwise direction of the gate electrode 430′, the active layer 410′ comprises an acute point 415′ on each of two sides thereof. When the TFT 400′ is in operation, the acute points 415′ on the two sides of the active layer 410′ cause an effect of electric field concentration so that increased concentration of charge carriers will be induced in the acute points 415′, forming a parasitic TFT on the side surfaces, thereby changing the electrical property of the output of the TFT 400′, leading to undesired advanced conduction of the TFT and thus affecting normal displaying operations of a liquid crystal display panel.

### SUMMARY OF THE INVENTION

An object of the present invention is to provide a thin-film transistor (TFT) substrate, which prevents an active layer structure from affecting electrical property of output of the TFT so as to provide high quality of TFT and high operation stability.

Another object of the present invention is to provide a manufacture method of a TFT substrate, which prevents an active layer structure from affecting electrical property of output of the TFT so as to improve quality of TFT and enhance operation stability of the TFT substrate.

To achieve the above objects, the present invention provides a TFT substrate, which comprises a backing plate and a TFT arranged on the backing plate;

wherein the TFT comprises an active layer, a gate insulation layer arranged on the active layer, a gate electrode arranged on the gate insulation layer and having a horizontal position corresponding to the active layer, an interlayer dielectric layer arranged on the gate electrode and the gate insulation layer, and a source electrode and a drain electrode arranged on the interlayer dielectric layer; and

in a lengthwise direction of the gate electrode, the active layer comprises, at least, a first zone located in the middle and second zones located on two opposite sides of the first zone, the first zone having a thickness that is greater than a thickness of the second zones so that the two sides the active layer each form at least one step.

The two sides of the active layer each comprise one step.

The TFT substrate further comprises a light-shielding layer and a buffer layer arranged between the backing plate and the TFT, a planarization layer arranged on the TFT, a bottom electrode arranged on the planarization layer, a passivation layer arranged on the bottom electrode, and a top electrode arranged on the passivation layer.

The active layer and the light-shielding layer correspond to each other and the light-shielding layer completely covers the active layer in the horizontal direction.

The gate insulation layer and the interlayer dielectric layer comprise a first via and a second via formed therein to respectively correspond, in position, to two ends of the active layer and the source electrode and the drain electrode are respectively connected through the first via and the second via to the two ends of the active layer; and

the planarization layer comprises a third via formed therein at a location corresponding to the drain electrode and the top electrode is connected through the third via to the drain electrode.

The present invention also provides a manufacture method of a TFT substrate, which comprises the following steps:

(1) providing a backing plate, forming a semiconductor material layer on the backing plate, forming a photoresist layer on the semiconductor material layer, and applying a mask to subject the photoresist layer to exposure and development so as to obtain a photoresist pattern, wherein in the lengthwise direction of a gate electrode, the photoresist pattern comprises, at least, a first photoresist section located in the middle and second photoresist sections located on two sides and the first photoresist section has a thickness that is greater than a thickness of the second photoresist sections;

(2) applying a gas that is capable of etching the photoresist pattern and the semiconductor material layer to subject the photoresist pattern and the semiconductor material layer to at least two etching operations,

wherein a first etching operation is such that portions of the semiconductor material layer that are located on outer sides of the second photoresist sections are thinned and at the same time, the first photoresist section of the photoresist pattern is thinned and the second photoresist sections of the photoresist pattern are completely etched off and removed, and

a second etching operation is such that the first photoresist section of the photoresist pattern is completely etched off and removed and the portions of the semiconductor material layer that are located on the outer sides of the second photoresist sections are completely etched off and removed, and at the same time, portions of the semiconductor material layer that correspond to the second photoresist sections are thinned to obtain the active layer, wherein the active layer comprises, at least, a first zone that is located in the middle and corresponds to the first photoresist section and second zones that are located on two opposite sides of the first zone and correspond respectively to the second photoresist sections, the first zone having a thickness that is greater than a thickness of the second zones, such that the two sides of the active layer each comprise at least one step; and

(3) forming a gate insulation layer on the active layer, forming a gate electrode on the gate insulation layer at a location corresponding to the active layer, forming an interlayer dielectric layer on the gate electrode and the gate insulation layer, and forming a source electrode and a drain electrode on the interlayer dielectric layer to form a TFT.

The active layer formed in step (2) comprises one step on each of the two sides thereof.

Step (1) further comprises a sub-step of forming a light-shielding layer and a buffer layer between the backing plate and the semiconductor material layer; and

a step (4) is further included for forming a planarization layer on the TFT, forming a bottom electrode on the planarization layer, forming a passivation layer on the bottom electrode, and forming a top electrode on the passivation layer.

The active layer formed in step (2) and the light-shielding layer correspond to each other and the light-shielding layer completely covers the active layer in the horizontal direction.

Step (3) further comprises a sub-step of forming a first via and a second via in the gate insulation layer and the interlayer dielectric layer at locations corresponding to two opposite ends of the active layer such that the source electrode and the drain electrode are respectively connected through the first via and the second via to the two ends of the active layer; and

step (4) further comprises a sub-step of forming a third via in the planarization layer at a location corresponding to the drain electrode such that the top electrode is connected through the third via to the drain electrode.

The present invention further provides a manufacture method of a TFT substrate, which comprises the following steps:

(1) providing a backing plate, forming a semiconductor material layer on the backing plate, forming a photoresist layer on the semiconductor material layer, and applying a mask to subject the photoresist layer to exposure and development so as to obtain a photoresist pattern, wherein in the lengthwise direction of a gate electrode, the photoresist pattern comprises, at least, a first photoresist section located in the middle and second photoresist sections located on two sides and the first photoresist section has a thickness that is greater than a thickness of the second photoresist sections;

(2) applying a gas that is capable of etching the photoresist pattern and the semiconductor material layer to subject the photoresist pattern and the semiconductor material layer to at least two etching operations,

wherein a first etching operation is such that portions of the semiconductor material layer that are located on outer sides of the second photoresist sections are thinned and at the same time, the first photoresist section of the photoresist pattern is thinned and the second photoresist sections of the photoresist pattern are completely etched off and removed, and

a second etching operation is such that the first photoresist section of the photoresist pattern is completely etched off and removed and the portions of the semiconductor material layer that are located on the outer sides of the second photoresist sections are completely etched off and removed, and at the same time, portions of the semiconductor material layer that correspond to the second photoresist sections are thinned to obtain the active layer, wherein the active layer comprises, at least, a first zone that is located in the middle and corresponds to the first photoresist section and second zones that are located on two opposite sides of the first zone and correspond respectively to the second photoresist sections, the first zone having a thickness that is greater than a thickness of the second zones, such that the two sides of the active layer each comprise at least one step; and

(3) forming a gate insulation layer on the active layer, forming a gate electrode on the gate insulation layer at a location corresponding to the active layer, forming an interlayer dielectric layer on the gate electrode and the gate insulation layer, and forming a source electrode and a drain electrode on the interlayer dielectric layer to form a TFT;

wherein the active layer formed in step (2) comprises one step on each of the two sides thereof; and

wherein step (1) further comprises a sub-step of forming a light-shielding layer and a buffer layer between the backing plate and the semiconductor material layer; and

a step (4) is further included for forming a planarization layer on the TFT, forming a bottom electrode on the planarization layer, forming a passivation layer on the bottom electrode, and forming a top electrode on the passivation layer.

The efficacy of the present invention is that the present invention provides a TFT substrate, which comprises: a backing plate and a TFT arranged on the backing plate. The TFT substrate involve modifications made of the structure of the active layer of the TFT to form at least one step on each of two side portions of the active layer. Compared to an active layer of the prior art, electric field concentration effect at acute points on two side surfaces of the active layer can be effectively reduced, making charge carrier concentration in the interior of the active layer uniform and electrical property of output of the TFT stable, whereby the quality of the TFT is made high and the operation stability of the TFT substrate is enhanced. The present invention provides a manufacture method of a TFT substrate, which effectively reduces electric field concentration effect at acute points on side surfaces of an active layer of a TFT, making charge carrier concentration in the interior of the active layer uniform and electrical property of output of the TFT stable, whereby the quality of the TFT is made high and the operation stability of the TFT substrate is enhanced.

### BRIEF DESCRIPTION OF THE DRAWINGS

The features and technical contents of the present invention will be better understood by referring to the following detailed description and drawings the present invention. However, the drawings are provided for the purpose of reference and illustration and are not intended to limit the scope of the present invention. In the drawing:

FIG. 1 is a schematic view illustrating the structure of a conventional thin-film transistor (TFT) substrate;

FIG. 2 is a top plan view showing a TFT of the TFT substrate of FIG. 1;

FIG. 3 is a cross-sectional view of the TFT of the TFT substrate of FIG. 1 taken along line A′-A′ of FIG. 2;

FIG. 4 is a schematic view illustrating the structure of a TFT substrate according to the present invention;

FIG. 5 is a top plan view showing a TFT of the TFT substrate of FIG. 4;

FIG. 6 is a cross-sectional view of the TFT of the TFT substrate of FIG. 4 taken along line A-A of FIG. 5;

FIG. 7 is a flow chart illustrating a manufacture method of a TFT substrate according to the present invention;

FIGS. 8 and 9 are schematic views illustrating Step 1 of the manufacture method of a TFT substrate according to the present invention; and

FIGS. 10 and 11 are schematic views illustrating Step 2 of the manufacture method of a TFT substrate according to the present invention.

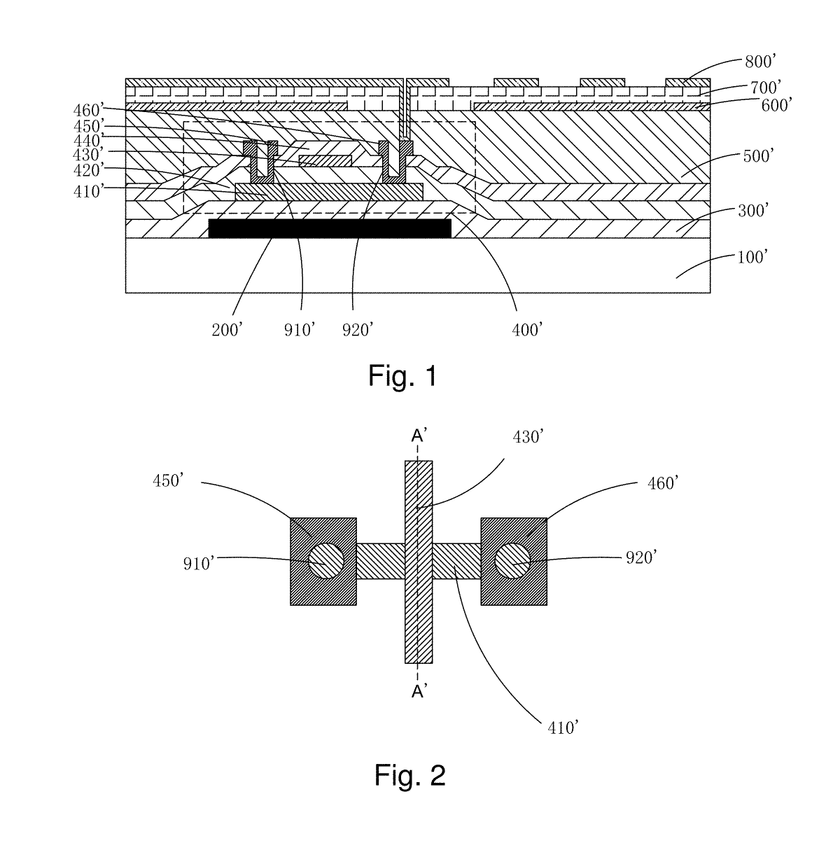

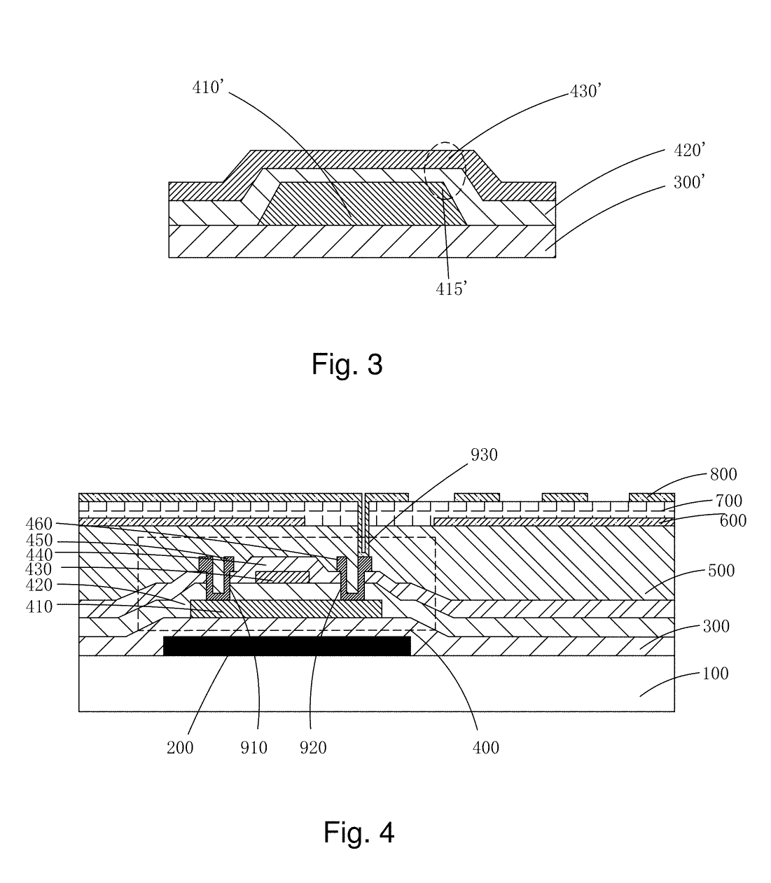

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

Referring to FIGS. 4-6, the present invention provides a thin-film transistor (TFT) substrate, which comprises a backing plate 100 and a TFT 400 arranged on the backing plate 100.

The TFT 400 comprises an active layer 410, a gate insulation layer 420 arranged on the active layer 410, a gate electrode 430 arranged on the gate insulation layer 420 and having a horizontal position corresponding to the active layer 410, an interlayer dielectric layer 440 arranged on the gate electrode 430 and the gate insulation layer 420, and a source electrode 450 and a drain electrode 460 arranged on the interlayer dielectric layer 440.

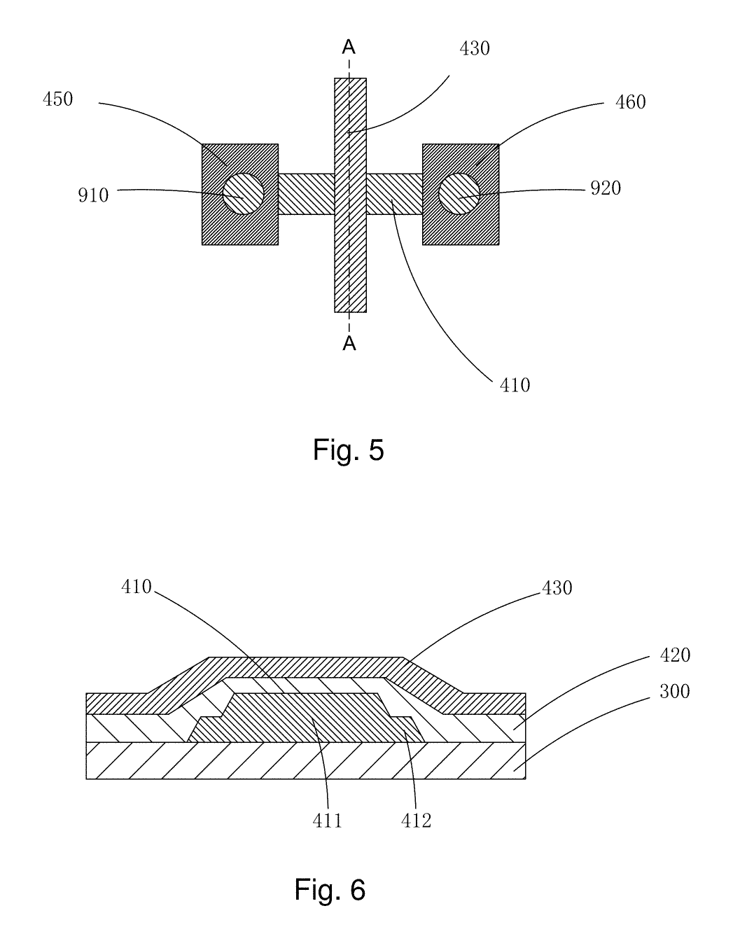

As shown in FIGS. 5-6, in a lengthwise direction of the gate electrode 430, the active layer 410 comprises, at least, a first zone 411 located in the middle and second zones 412 located on two opposite sides of the first zone 411. The first zone 411 has a thickness that is greater than a thickness of the second zones 412 so that the two sides the active layer 410 each form at least one step.

Preferably, the second zones 412 have a width that is one twentieth to one tenth of a width of the first zone 411.

Preferably, the two sides of the active layer 410 each comprise one step.

Specifically, the TFT substrate further comprises a light-shielding layer 200 and a buffer layer 300 arranged between the backing plate 100 and the TFT 400, a planarization layer 500 arranged on the TFT 400, a bottom electrode 600 arranged on the planarization layer 500, a passivation layer 700 arranged on the bottom electrode 600, and a top electrode 800 arranged on the passivation layer 700.

Specifically, the active layer 410 and the light-shielding layer 200 correspond to each other and the light-shielding layer 200 completely covers the active layer 410 in the horizontal direction so as to shield light for the active layer 410 and prevent a photoelectric effect to cause leakage current in the TFT to affect displaying performance.

Specifically, the gate insulation layer 420 and the interlayer dielectric layer 440 comprise a first via 910 and a second via 920 formed therein to respectively correspond, in position, to two ends of the active layer 410. The source electrode 450 and the drain electrode 460 are respectively connected, through the first via 910 and the second via 920, to the two ends of the active layer 410.

The planarization layer 500 comprises a third via 930 formed therein at a location corresponding to the drain electrode 460. The top electrode 800 is connected through the third via 930 to the drain electrode 460.

Preferably, the backing plate 100 comprises a glass substrate.

Specifically, the bottom electrode 600 and the top electrode 800 are respectively a common electrode and a pixel electrode. The bottom electrode 600 and the top electrode 800 are formed of materials that are both transparent conductive materials. The transparent conductive materials are preferably indium tin oxides (ITO).

Specifically, the active layer 410 is formed of a material comprising poly-silicon (Poly-Si).

In the above-described TFT substrate, modifications are made on the structure of an active layer 410 of a TFT 400 to form at least one step on each of two side portions of the active layer 400. Compared to an active layer of the prior art, the active layer 410 show reduced electric field concentration effect on the two sides thereof so that charge carrier concentration in the interior of the active layer 410 is uniform, preventing the side surfaces of the active layer 410 and the gate electrode 430 on the top thereof from generating a parasitic TFT, thereby effectively controlling electrical property of output of the TFT 400, improving quality of the TFT 400, and thus enhancing operation stability of the TFT substrate.

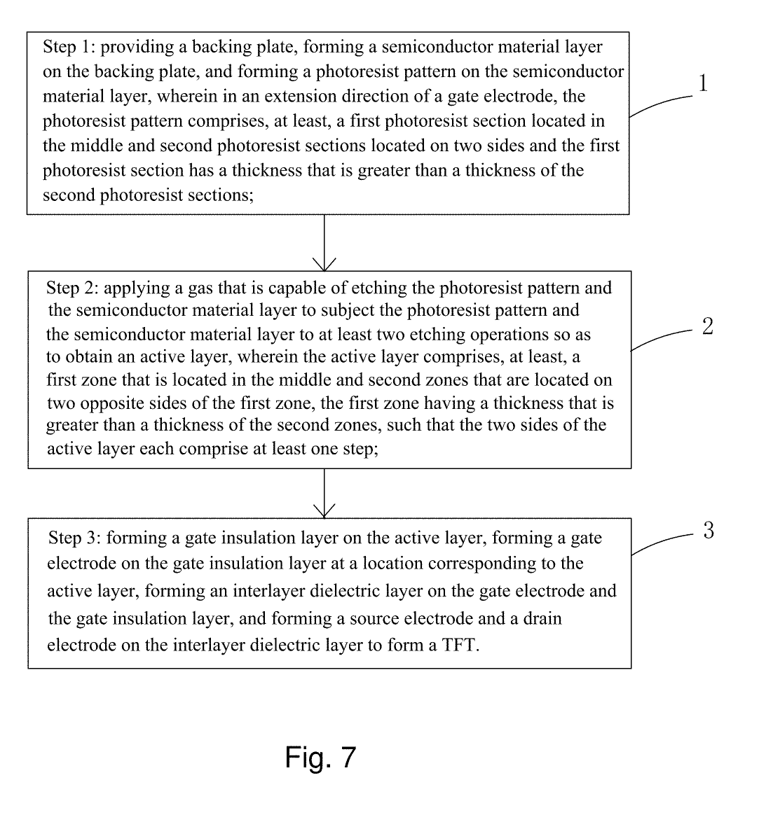

Referring to FIG. 7, on the basis of the above-described TFT substrate, the present invention also provides a manufacture method of a TFT substrate, which comprises the following steps:

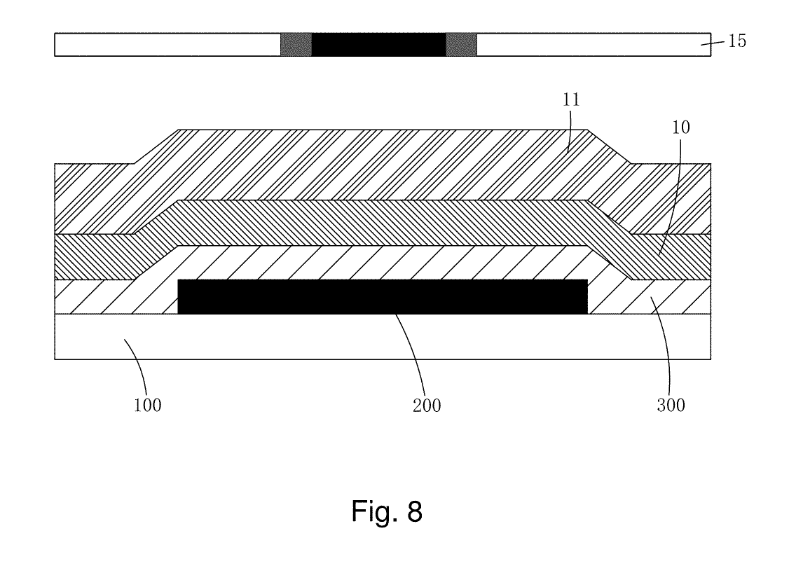

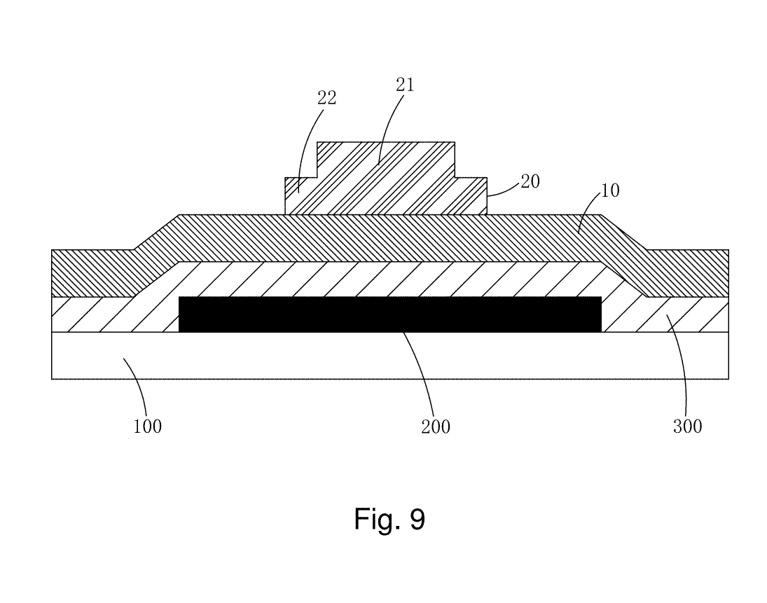

Step 1: as shown in FIGS. 8-9, providing a backing plate 100, forming a semiconductor material layer 10 on the backing plate 100, forming a photoresist layer 11 on the semiconductor material layer 10, and applying a mask 15 to subject the photoresist layer 11 to exposure and development so as to obtain a photoresist pattern 20, wherein in the lengthwise direction of a gate electrode, the photoresist pattern 20 comprises, at least, a first photoresist section 21 located in the middle and second photoresist sections 22 located on two sides and the first photoresist section 21 has a thickness that is greater than a thickness of the second photoresist sections 22.

Specifically, as shown in FIG. 8, Step 1 further comprises a sub-step of forming a light-shielding layer 200 and a buffer layer 300 between the backing plate 100 and the semiconductor material layer 10.

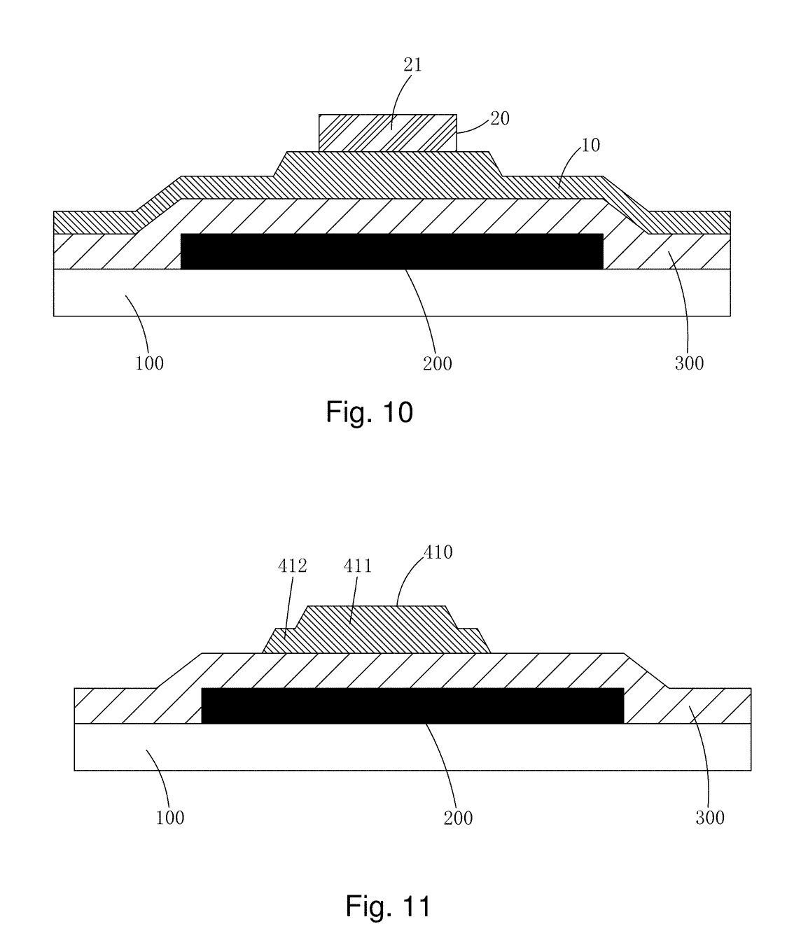

Step 2: as shown in FIGS. 10-11, applying a gas that is capable of etching the photoresist pattern 20 and the semiconductor material layer 10 to subject the photoresist pattern 20 and the semiconductor material layer 10 to at least two etching operations.

As shown in FIG. 10, the first etching operation is such that portions of the semiconductor material layer 10 that are located on outer sides of the second photoresist sections 22 are thinned and at the same time, the first photoresist section 21 of the photoresist pattern 20 is thinned and the second photoresist sections 22 of the photoresist pattern 20 are completely etched off and removed.

As shown in FIG. 11, the second etching operation is such that the first photoresist section 21 of the photoresist pattern 20 is completely etched off and removed and the portions of the semiconductor material layer 10 that are located on the outer sides of the second photoresist sections 22 are completely etched off and removed, and at the same time, portions of the semiconductor material layer 10 that correspond to the second photoresist sections 22 are thinned to obtain the active layer 410, wherein the active layer 410 comprises, at least, a first zone 411 that is located in the middle and corresponds to the first photoresist section 21 and second zones 412 that are located on two opposite sides of the first zone 411 and correspond respectively to the second photoresist sections 22, the first zone 411 having a thickness that is greater than a thickness of the second zones 412, such that the two sides of the active layer 410 each comprise at least one step.

Preferably, the active layer 410 formed in Step 2 comprises one step on each of the two sides thereof.

Specifically, in Step 2, the mask 15 used is a gray tone mask (GTM), a half tone mask (HTM), or a single slit mask (SSM).

Specifically, the etchant gas used in Step 2 has multiple components respectively comprising different kinds of gas such that by adjusting the ratio among the components of the different gases, a desired ratio between an etching speed of the etchant gas on the semiconductor material layer 10 and an etching speed of the etchant gas on the photoresist pattern 20 can be obtained.

Specifically, the first etching operation and the second etching operation are both dry etching.

Specifically, the active layer 410 formed in Step 2 and the light-shielding layer 200 correspond to each other and the light-shielding layer 200 completely covers the active layer 410 in the horizontal direction so as to shield light for the active layer 410 and prevent a photoelectric effect to cause leakage current in the TFT to affect displaying performance.

Step 3: as shown in FIG. 4, forming a gate insulation layer 420 on the active layer 410, forming a gate electrode 430 on the gate insulation layer 420 at a location corresponding to the active layer 410, forming an interlayer dielectric layer 440 on the gate electrode 430 and the gate insulation layer 420, and forming a source electrode 450 and a drain electrode 460 on the interlayer dielectric layer 440 to form a TFT 400.

Specifically, as shown in FIG. 4, the manufacture method of a TFT substrate further comprises: Step 4, forming a planarization layer 500 on the TFT 400, forming a bottom electrode 600 on the planarization layer 500, forming a passivation layer 700 on the bottom electrode 600, and forming a top electrode 800 on the passivation layer 700.

Specifically, as shown in FIG. 4, Step 3 further comprises a sub-step of forming a first via 910 and a second via 920 in the gate insulation layer 420 and the interlayer dielectric layer 440 at locations corresponding to two opposite ends of the active layer 410 such that the source electrode 450 and the drain electrode 460 are respectively connected through the first via 910 and the second via 920 to the two ends of the active layer 410.

Step 4 further comprises a sub-step of forming a third via 930 in the planarization layer 500 at a location corresponding to the drain electrode 460 such that the top electrode 800 is connected through the third via 930 to the drain electrode 460.

Preferably, the backing plate 100 comprises a glass substrate.

Specifically, the bottom electrode 600 and the top electrode 800 are respectively a common electrode and a pixel electrode. The bottom electrode 600 and the top electrode 800 are formed of materials that are both transparent conductive materials. The transparent conductive materials are preferably indium tin oxides (ITO).

Specifically, the active layer 410 is formed of a material comprising poly-silicon (Poly-Si).

In the above-described manufacture method of a TFT substrate, modifications are made on the structure of an active layer 410 of a TFT 400 to form at least one step on each of two side portions of the active layer 400. Compared to an active layer of the prior art, the active layer 410 show reduced electric field concentration effect on the two sides thereof so that charge carrier concentration in the interior of the active layer 410 is uniform, preventing the side surfaces of the active layer 410 and the gate electrode 430 on the top thereof from generating a parasitic TFT, thereby effectively controlling electrical property of output of the TFT 400, improving quality of the TFT 400, and thus enhancing operation stability of the TFT substrate.

In summary, the present invention provides a TFT substrate, which comprises: a backing plate and a TFT arranged on the backing plate. The TFT substrate involve modifications made of the structure of the active layer of the TFT to form at least one step on each of two side portions of the active layer. Compared to an active layer of the prior art, electric field concentration effect at acute points on two side surfaces of the active layer can be effectively reduced, making charge carrier concentration in the interior of the active layer uniform and electrical property of output of the TFT stable, whereby the quality of the TFT is made high and the operation stability of the TFT substrate is enhanced. The present invention provides a manufacture method of a TFT substrate, which effectively reduces electric field concentration effect at acute points on side surfaces of an active layer of a TFT, making charge carrier concentration in the interior of the active layer uniform and electrical property of output of the TFT stable, whereby the quality of the TFT is made high and the operation stability of the TFT substrate is enhanced.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A thin-film transistor (TFT) substrate, comprising a backing plate and a TFT arranged on the backing plate;
wherein the TFT comprises an active layer, a gate insulation layer arranged on the active layer, a gate electrode arranged on the gate insulation layer and having a horizontal position corresponding to the active layer, an interlayer dielectric layer arranged on the gate electrode and the gate insulation layer, and a source electrode and a drain electrode arranged on the interlayer dielectric layer; and
in a lengthwise direction of the gate electrode, the active layer comprises, at least, a first zone located in the middle and second zones located on two opposite sides of the first zone, the first zone having a thickness that is greater than a thickness of the second zones so that the two sides the active layer each form at least one step.

2. The TFT substrate as claimed in claim 1, wherein the two sides of the active layer each comprise one step.

3. The TFT substrate as claimed in claim 1 further comprising a light-shielding layer and a buffer layer arranged between the backing plate and the TFT, a planarization layer arranged on the TFT, a bottom electrode arranged on the planarization layer, a passivation layer arranged on the bottom electrode, and a top electrode arranged on the passivation layer.

4. The TFT substrate as claimed in claim 3, wherein the active layer and the light-shielding layer correspond to each other and the light-shielding layer completely covers the active layer in the horizontal direction.

5. The TFT substrate as claimed in claim 3, wherein the gate insulation layer and the interlayer dielectric layer comprise a first via and a second via formed therein to respectively correspond, in position, to two ends of the active layer and the source electrode and the drain electrode are respectively connected through the first via and the second via to the two ends of the active layer; and
the planarization layer comprises a third via formed therein at a location corresponding to the drain electrode and the top electrode is connected through the third via to the drain electrode.

6. A manufacture method of a thin-film transistor (TFT) substrate, comprising the following steps:
(1) providing a backing plate, forming a semiconductor material layer on the backing plate, forming a photoresist layer on the semiconductor material layer, and applying a mask to subject the photoresist layer to exposure and development so as to obtain a photoresist pattern, wherein in the lengthwise direction of a gate electrode, the photoresist pattern comprises, at least, a first photoresist section located in the middle and second photoresist sections located on two sides and the first photoresist section has a thickness that is greater than a thickness of the second photoresist sections;
(2) applying a gas that is capable of etching the photoresist pattern and the semiconductor material layer to subject the photoresist pattern and the semiconductor material layer to at least two etching operations,
wherein a first etching operation is such that portions of the semiconductor material layer that are located on outer sides of the second photoresist sections are thinned and at the same time, the first photoresist section of the photoresist pattern is thinned and the second photoresist sections of the photoresist pattern are completely etched off and removed, and
a second etching operation is such that the first photoresist section of the photoresist pattern is completely etched off and removed and the portions of the semiconductor material layer that are located on the outer sides of the second photoresist sections are completely etched off and removed, and at the same time, portions of the semiconductor material layer that correspond to the second photoresist sections are thinned to obtain the active layer, wherein the active layer comprises, at least, a first zone that is located in the middle and corresponds to the first photoresist section and second zones that are located on two opposite sides of the first zone and correspond respectively to the second photoresist sections, the first zone having a thickness that is greater than a thickness of the second zones, such that the two sides of the active layer each comprise at least one step; and
(3) forming a gate insulation layer on the active layer, forming a gate electrode on the gate insulation layer at a location corresponding to the active layer, forming an interlayer dielectric layer on the gate electrode and the gate insulation layer, and forming a source electrode and a drain electrode on the interlayer dielectric layer to form a TFT.

7. The manufacture method of a TFT substrate as claimed in claim 1, wherein the active layer formed in step (2) comprises one step on each of the two sides thereof.

8. The manufacture method of a TFT substrate as claimed in claim 6, wherein step (1) further comprises a sub-step of forming a light-shielding layer and a buffer layer between the backing plate and the semiconductor material layer; and
a step (4) is further included for forming a planarization layer on the TFT, forming a bottom electrode on the planarization layer, forming a passivation layer on the bottom electrode, and forming a top electrode on the passivation layer.

9. The manufacture method of a TFT substrate as claimed in claim 8, wherein the active layer formed in step (2) and the light-shielding layer correspond to each other and the light-shielding layer completely covers the active layer in the horizontal direction.

10. The manufacture method of a TFT substrate as claimed in claim 8, wherein step (3) further comprises a sub-step of forming a first via and a second via in the gate insulation layer and the interlayer dielectric layer at locations corresponding to two opposite ends of the active layer such that the source electrode and the drain electrode are respectively connected through the first via and the second via to the two ends of the active layer; and
step (4) further comprises a sub-step of forming a third via in the planarization layer at a location corresponding to the drain electrode such that the top electrode is connected through the third via to the drain electrode.

11. A manufacture method of a thin-film transistor (TFT) substrate, comprising the following steps:
(1) providing a backing plate, forming a semiconductor material layer on the backing plate, forming a photoresist layer on the semiconductor material layer, and applying a mask to subject the photoresist layer to exposure and development so as to obtain a photoresist pattern, wherein in the lengthwise direction of a gate electrode, the photoresist pattern comprises, at least, a first photoresist section located in the middle and second photoresist sections located on two sides and the first photoresist section has a thickness that is greater than a thickness of the second photoresist sections;
(2) applying a gas that is capable of etching the photoresist pattern and the semiconductor material layer to subject the photoresist pattern and the semiconductor material layer to at least two etching operations,
wherein a first etching operation is such that portions of the semiconductor material layer that are located on outer sides of the second photoresist sections are thinned and at the same time, the first photoresist section of the photoresist pattern is thinned and the second photoresist sections of the photoresist pattern are completely etched off and removed, and
a second etching operation is such that the first photoresist section of the photoresist pattern is completely etched off and removed and the portions of the semiconductor material layer that are located on the outer sides of the second photoresist sections are completely etched off and removed, and at the same time, portions of the semiconductor material layer that correspond to the second photoresist sections are thinned to obtain the active layer, wherein the active layer comprises, at least, a first zone that is located in the middle and corresponds to the first photoresist section and second zones that are located on two opposite sides of the first zone and correspond respectively to the second photoresist sections, the first zone having a thickness that is greater than a thickness of the second zones, such that the two sides of the active layer each comprise at least one step; and
(3) forming a gate insulation layer on the active layer, forming a gate electrode on the gate insulation layer at a location corresponding to the active layer, forming an interlayer dielectric layer on the gate electrode and the gate insulation layer, and forming a source electrode and a drain electrode on the interlayer dielectric layer to form a TFT;
wherein the active layer formed in step (2) comprises one step on each of the two sides thereof; and
wherein step (1) further comprises a sub-step of forming a light-shielding layer and a buffer layer between the backing plate and the semiconductor material layer; and
a step (4) is further included for forming a planarization layer on the TFT, forming a bottom electrode on the planarization layer, forming a passivation layer on the bottom electrode, and forming a top electrode on the passivation layer.

12. The manufacture method of a TFT substrate as claimed in claim 11, wherein the active layer formed in step (2) and the light-shielding layer correspond to each other and the light-shielding layer completely covers the active layer in the horizontal direction.

13. The manufacture method of a TFT substrate as claimed in claim 11, wherein step (3) further comprises a sub-step of forming a first via and a second via in the gate insulation layer and the interlayer dielectric layer at locations corresponding to two opposite ends of the active layer such that the source electrode and the drain electrode are respectively connected through the first via and the second via to the two ends of the active layer; and
step (4) further comprises a sub-step of forming a third via in the planarization layer at a location corresponding to the drain electrode such that the top electrode is connected through the third via to the drain electrode.
